(19) United States
(12) Patent Application Publication
(10) Pub. No.: US 2026/0293038 A1
(43) Pub. Date: Sep. 24, 2026

(54) Server System Fan System

(71) Applicant: Dell Products L.P., Round Rock, TX (US)

(72) Inventors: Hsu-Chu Wang, Taipei (TW); Hsiang-Yin Hung, Taipei (TW)

(21) Appl. No.: 19/086,195

(22) Filed: Mar. 21, 2025

(51) Int. Cl. H05K 7/20; G06F 1/20

(52) U.S. Cl. CPC H05K 7/20172; G06F 1/20; H05K 7/20727

(57) ABSTRACT

A fan system for use with an information handling system. The fan system includes a fan system housing and, a fan system connector system, the fan system connector system including a fan system housing connector, the fan system housing connector defining a fan system housing connector aperture and a fan system housing connector fastener mechanism, the fan system housing connector fastener mechanism comprising a fan system housing fastener and a fan system housing fastener positioning component, the fan system housing connector fastener mechanism being configured to attach the fan system housing connector to the fan system housing, the fan system housing connector fastener mechanism being configured to fit within the fan system housing connector aperture.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing an information handling system with a fan system.

In one embodiment, the invention relates to a fan system connector system for use with an information handling system, comprising: a fan system housing connector, the fan system housing connector defining a fan system housing connector aperture; and, a fan system housing connector fastener mechanism, the fan system housing connector fastener mechanism comprising a fan system housing fastener and a fan system housing fastener positioning component, the fan system housing connector fastener mechanism being configured to attach the fan system housing connector to a fan system housing, the fan system housing connector fastener mechanism being configured to fit within the fan system housing connector aperture.

In another embodiment, the invention relates to a fan system comprising: a fan system housing and a fan system connector system, the fan system connector system comprising: a fan system housing connector, the fan system housing connector defining a fan system housing connector aperture; and, a fan system housing connector fastener mechanism, the fan system housing connector fastener mechanism comprising a fan system housing fastener and a fan system housing fastener positioning component, the fan system housing connector fastener mechanism being configured to attach the fan system housing connector to the fan system housing, the fan system housing connector fastener mechanism being configured to fit within the fan system housing connector aperture.

In another embodiment, the invention relates to a system comprising: a chassis; a component array and a fan system, the fan system comprising a fan system housing and a fan system connector system, the fan system connector system comprising: a fan system housing connector, the fan system housing connector defining a fan system housing connector aperture; and, a fan system housing connector fastener mechanism, the fan system housing connector fastener mechanism comprising a fan system housing fastener and a fan system housing fastener positioning component, the fan system housing connector fastener mechanism being configured to attach the fan system housing connector to the fan system housing, the fan system housing connector fastener mechanism being configured to fit within the fan system housing connector aperture.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A, 4B, 4C and 4D, generally referred to as FIG. 4, show views of a portion of a server type information handling system which includes a fan system.

FIGS. 5A, 5B, 5C and 5D, generally referred to as FIG. 5, show views of a fan system connector system.

FIGS. 6A and 6B, generally referred to as FIG. 6, show views of a fan system connector system.

### DETAILED DESCRIPTION

Various aspects of the disclosure include an appreciation that it is known to provide server type information handling systems with fan systems. Various aspects of the present disclosure include an appreciation that known fan systems often include a plurality of fans mounted within a fan system housing. Various aspects of the present disclosure include an appreciation that known fan systems are often coupled to other components of the server information handling system via fan system connections. Various aspects of the present disclosure include an appreciation that fan system connections are often configured with a floating fan system connector system.

Various aspects of the present disclosure include an appreciation that certain known fan systems with floating fan system connector system there can be a unilateral gap of between a screw of a fan system connector of the fan system connector system and a mating hole for the fan system connector on a fan system housing. Various aspects of the present disclosure include an appreciation that such a unilateral gap can cause the fan system connector to shift due to gravity. Various aspects of the present disclosure include an appreciation that certain known fan systems with floating fan system connectors this unilateral gap can be substantially (i.e., +/−20%) 1.0 mm between the screw and the mating hole of the connector which can result in a shift downward of substantially 1.0 mm due to gravity.

Various aspects of the present disclosure include an appreciation that certain known fan systems, the minimum distance between the fan system connector system and a lower system housing component (such as an air intake component or a component housing (e.g., a graphics processing unit (GPU) housing which includes a GPU heat sink) can be substantially (i.e., +/−20%) 0.4 mm. Various aspects of the present disclosure include an appreciation that certain known fan systems if a fan system connector of the fan system connector system shifts downward due to the unilateral gap, the lower system housing component can interfere with the fan system connector as the fan system connector is attached to the fan system housing. The combination of the unilateral gap and the minimum distance can be referred to as an accumulated tolerance.

Various aspects of the present disclosure include an appreciation that it would be desirable to provide a fan system which overcomes issues associated with the accumulated tolerance of the unilateral gap and the minimum distance between the fan system connector and the lower system housing component.

A system and method are disclosed for providing a server system with a fan system. In certain embodiments, the fan system includes a fan system connector system. In certain embodiments, the fan system connector system includes a fan system housing connector. In certain embodiments, the fan system housing connector includes a fan system housing connector aperture, a fan system connector fastener mechanism, or a combination thereof. In certain embodiments, the fan system connector fastener mechanism is configured to fit within the fan system housing connector aperture. In certain embodiments, the fan system connector fastener mechanism physically attaches the fan system housing connector to the fan system housing. In certain embodiments, the fan system housing connector is configured as a female type connector. In certain embodiments, the fan system housing connector is configured to interconnect with a fan system cable connector. In certain embodiments, the fan system cable connector is configured as a male type connector.

In certain embodiments, the fan system connector fastener mechanism includes a fan system fastener and a fan system connector positioning component. In certain embodiments, the fan system positioning component is configured as a right circular, open cylinder. In certain embodiments, the cylindrical fan system positioning component fits around the fan system fastener. In certain embodiments, the fan system fastener includes a fastener head, a fastener cylindrical portion and a fastener threaded portion. In certain embodiments, the cylindrical fan system positioning component fits around the fastener cylindrical portion. In certain embodiments, the fan system positioning component is configured with an elastomeric material. Inc certain embodiments, the elastomeric material is rubber.

In certain embodiments, the fan system positioning component is sized to fill the gap between the fan system fastener and the fan system housing connector aperture. In certain embodiments, so positioning the fan system positioning component ensures that the centers of the fan system fastener and the fan system housing connector aperture align, thereby preventing the fan system connector from shifting downward due to the gap. In certain embodiments, by maintaining the distance between the fan system housing connector and a lower housing component, this approach ensures that interference due to insufficient distance caused by accumulated tolerances is avoided.

Such a fan system may advantageously be assembled without complicated design alterations. Such a fan system may advantageously simultaneously achieve positioning and alignment of the fan system housing connector.

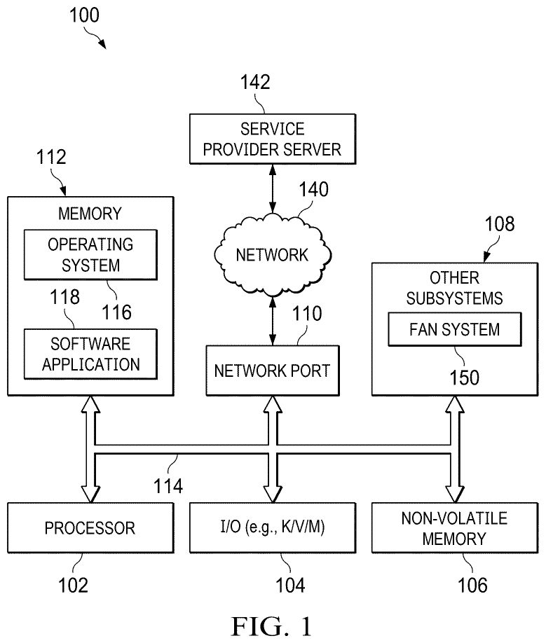

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a fan system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more fan system 150 for cooling of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the fan system 150 includes a fan system connector system. In certain embodiments, the fan system connector system includes a fan system housing connector. In certain embodiments, the fan system housing connector includes a fan system housing connector aperture, a fan system connector fastener mechanism, or a combination thereof. In certain embodiments, the fan system connector fastener mechanism is configured to fit within the fan system housing connector aperture. In certain embodiments, the fan system connector fastener mechanism physically attaches the fan system housing connector to the fan system housing. In certain embodiments, the fan system housing connector is configured as a female type connector. In certain embodiments, the fan system housing connector is configured to interconnect with a fan system cable connector. In certain embodiments, the fan system cable connector is configured as a male type connector.

In certain embodiments, the fan system connector fastener mechanism includes a fan system fastener and a fan system connector positioning component. In certain embodiments, the fan system positioning component is configured as a right circular, open cylinder. In certain embodiments, the cylindrical fan system positioning component fits around the fan system fastener. In certain embodiments, the fan system fastener includes a fastener head, a fastener cylindrical portion and a fastener threaded portion. In certain embodiments, the cylindrical fan system positioning component fits around the fastener cylindrical portion. In certain embodiments, the fan system positioning component is configured with an elastomeric material. Inc certain embodiments, the elastomeric material is rubber.

In certain embodiments, the fan system positioning component is sized to fill the gap between the fan system fastener and the fan system housing connector aperture. In certain embodiments, so positioning the fan system positioning component ensures that the centers of the fan system fastener and the fan system housing connector aperture align, thereby preventing the fan system connector from shifting downward due to the gap. In certain embodiments, by maintaining the distance between the fan system housing connector and a lower housing component, this approach ensures that interference due to insufficient distance caused by accumulated tolerances is avoided.

Such a fan system may advantageously be assembled without complicated design alterations. Such a fan system advantageously simultaneously achieves positioning and alignment of the fan system housing connector.

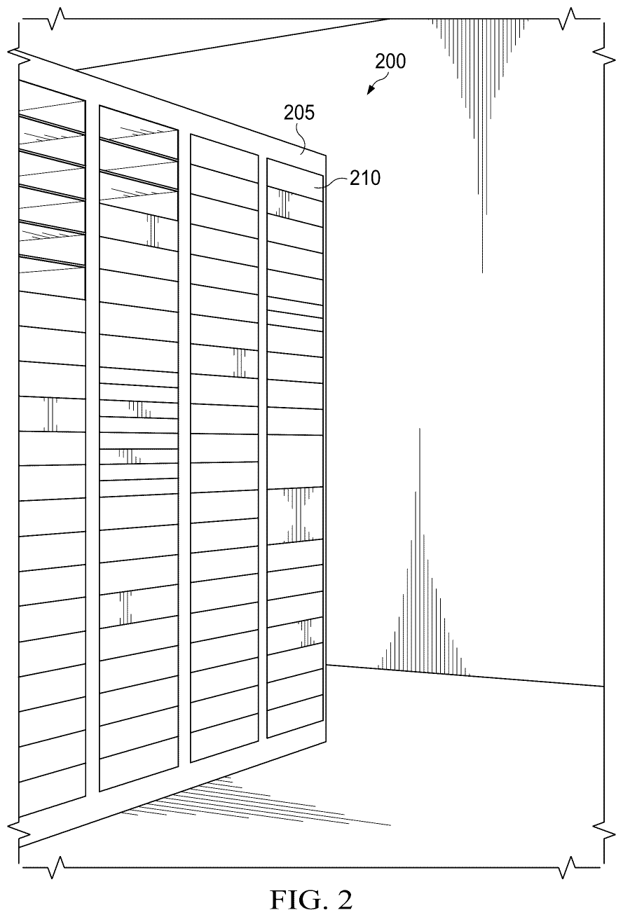

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

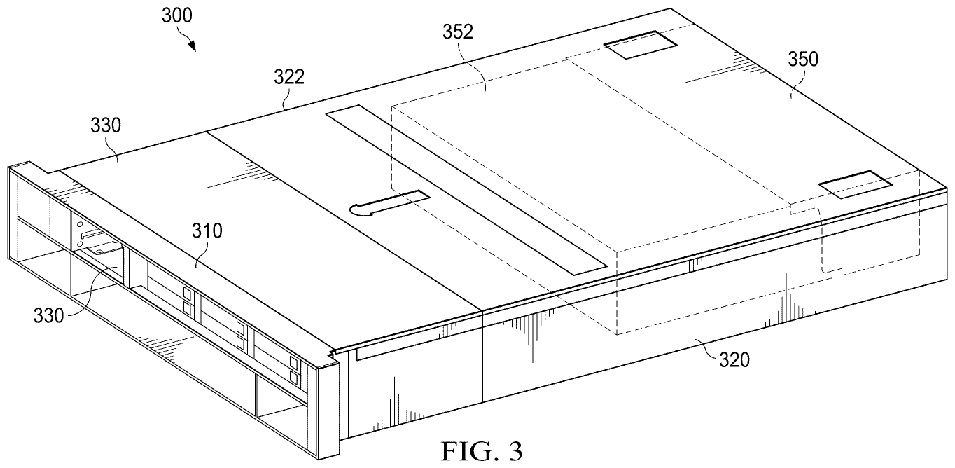

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300.

In certain embodiments, the blade type information handing system 300 includes a fan system 350 and a component array 352. In certain embodiments, a top of the fan system 350 extends over a portion of the component array 352. In certain embodiments, the component array 352 includes a GPU component array which includes a GPU component array housing. In certain embodiments, the GPU component array housing includes a GPU heat sink. In certain embodiments, GPU heat sink extends across some or all of a top portion of the GPU component array housing. In certain embodiments, a top of the fan system 350 extends over a portion of the GPU component array housing. In certain embodiments, a top of the fan system 350 extends over a portion of the CPU heat sink. In certain embodiments, the fan system 350 corresponds to fan system 150.

In certain embodiments, the fan system 350 includes a fan system connector system. In certain embodiments, the fan system connector system includes a fan system housing connector. In certain embodiments, the fan system housing connector includes a fan system housing connector aperture, a fan system connector fastener mechanism, or a combination thereof. In certain embodiments, the fan system connector fastener mechanism is configured to fit within the fan system housing connector aperture. In certain embodiments, the fan system connector fastener mechanism physically attaches the fan system housing connector to the fan system housing. In certain embodiments, the fan system housing connector is configured as a female type connector. In certain embodiments, the fan system housing connector is configured to interconnect with a fan system cable connector. In certain embodiments, the fan system cable connector is configured as a male type connector.

In certain embodiments, the fan system connector fastener mechanism includes a fan system fastener and a fan system connector positioning component. In certain embodiments, the fan system positioning component is configured as a right circular, open cylinder. In certain embodiments, the cylindrical fan system positioning component fits around the fan system fastener. In certain embodiments, the fan system fastener includes a fastener head, a fastener cylindrical portion and a fastener threaded portion. In certain embodiments, the cylindrical fan system positioning component fits around the fastener cylindrical portion. In certain embodiments, the fan system positioning component is configured with an elastomeric material. Inc certain embodiments, the elastomeric material is rubber.

In certain embodiments, the fan system positioning component is sized to fill the gap between the fan system fastener and the fan system housing connector aperture. In certain embodiments, so positioning the fan system positioning component ensures that the centers of the fan system fastener and the fan system housing connector aperture align, thereby preventing the fan system connector from shifting downward due to the gap. In certain embodiments, by maintaining the distance between the fan system housing connector and a lower housing component, this approach ensures that interference due to insufficient distance caused by accumulated tolerances is avoided.

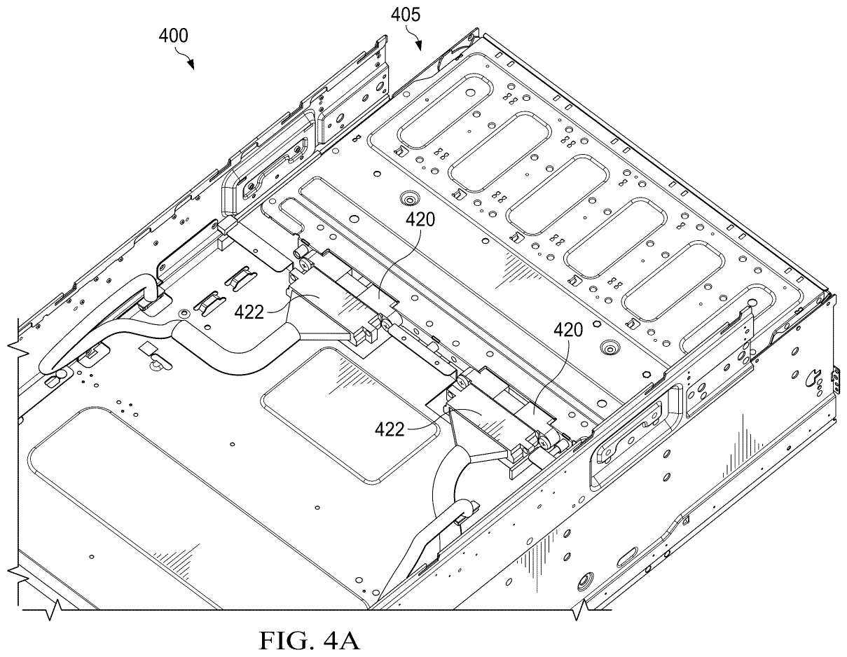

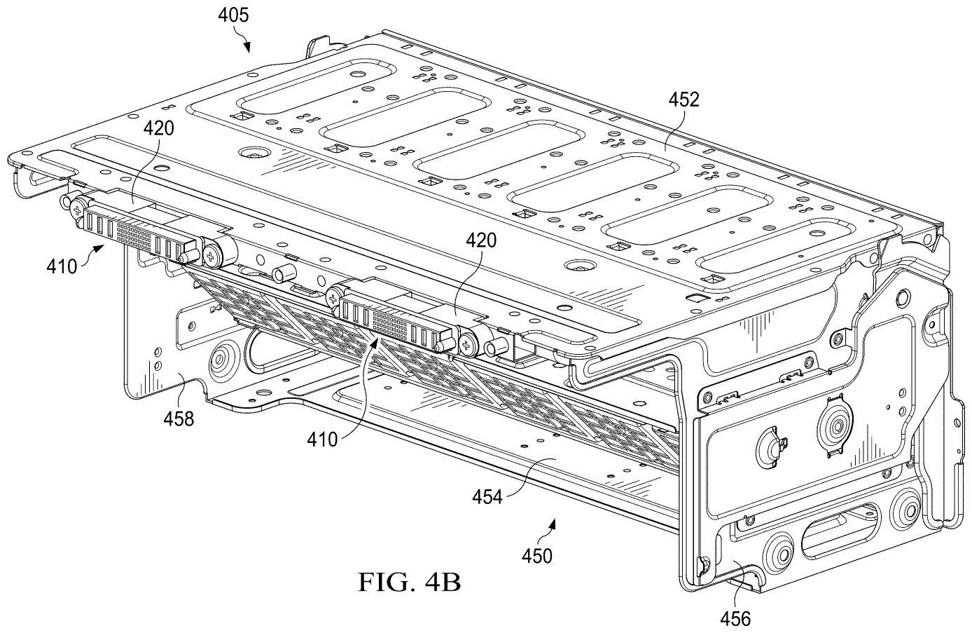

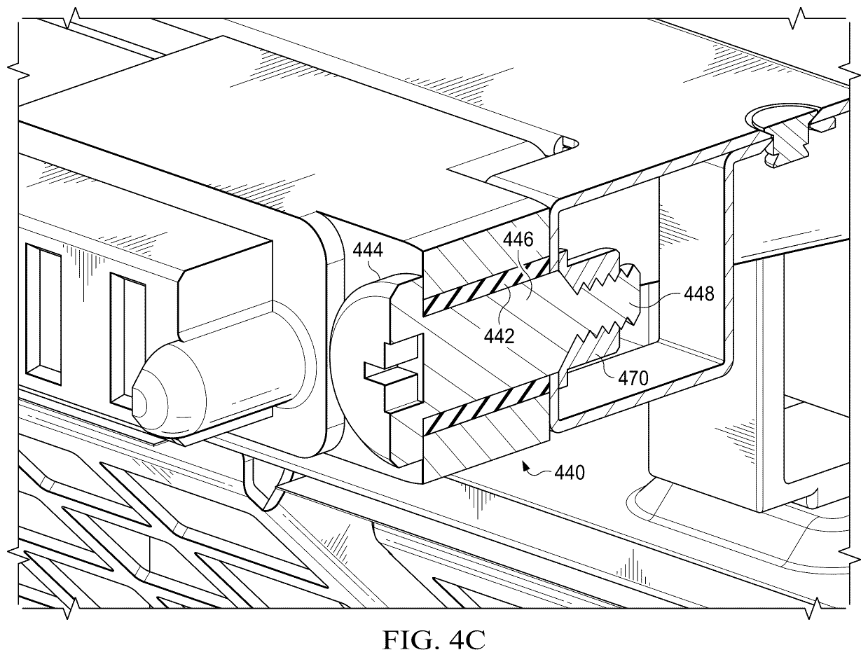

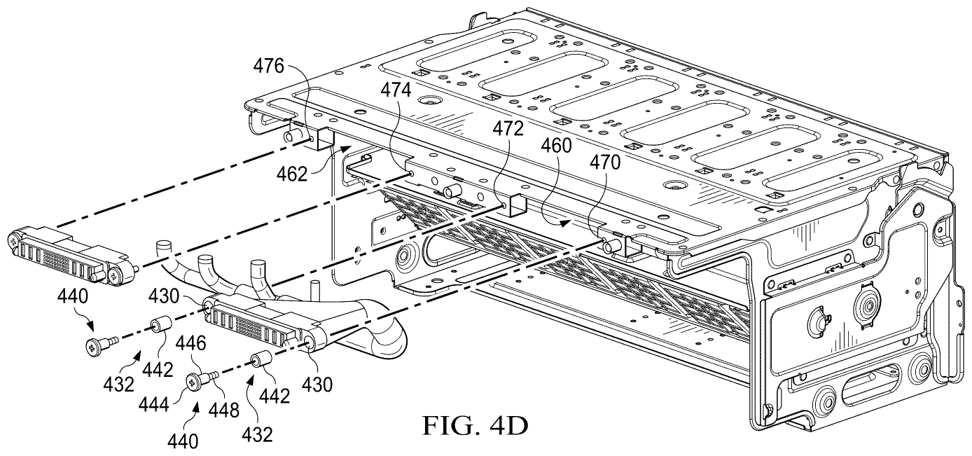

FIGS. 4A, 4B, 4C and 4D, generally referred to as FIG. 4, show views of a portion of server type information handling system 400 which includes a fan system 405. More specifically, FIG. 4a shows a perspective view of a portion of server type information handling system chassis in which a fan system 405 is mounted. FIG. 4B shows a perspective view of a fan system 405. FIG. 4C shows a cross-sectional view of a fan system connector system 410. FIG. 4D shows an exploded perspective view of a fan system 405. In certain embodiments, the fan system 405 corresponds to fan system 150.

In certain embodiments, the fan system 405 includes a fan system connector system 410. In certain embodiments, the fan system connector system 410 includes fan system housing connectors 420. In certain embodiments, the fan system housing connectors 420 are configured as a female type connector. In certain embodiments, the fan system housing connectors 420 are configured to interconnect with respective fan system cable connector 422. In certain embodiments, the fan system cable connector 422 is configured as a male type connector.

In certain embodiments, the fan system housing connector 420 includes a fan system housing connector aperture 430, a fan system connector fastener mechanism 432, or a combination thereof. In certain embodiments, the fan system connector fastener mechanism 432 is configured to fit within the fan system housing connector aperture 430.

In certain embodiments, the fan system connector fastener mechanism 432 includes a fan system fastener 440 and a fan system connector positioning component 442. In certain embodiments, the fan system positioning component 442 is configured as a right circular, open cylinder (i.e., a cylinder where both the top and bottom ends are closed to form an exterior surface and an interior surface with the interior surface defining a hole perpendicular to its base). In certain embodiments, the cylindrical fan system positioning component 442 fits around the fan system fastener 440. In certain embodiments, the fan system fastener 440 includes a fastener head 444, a fastener cylindrical portion 446 and a fastener threaded portion 448. In certain embodiments, the cylindrical fan system positioning component 442 fits around the fastener cylindrical portion 446. In certain embodiments, the fan system positioning component 442 is configured with an elastomeric material. In certain embodiments, the elastomeric material is rubber.

In certain embodiments, the fan system positioning component 442 is sized to fill the gap between the fan system fastener 440 and the fan system housing connector aperture 430. In certain embodiments, so positioning the fan system positioning component 442 ensures that the centers of the fan system fastener 440 and the fan system housing connector aperture 430 align, thereby preventing the fan system connector 420 from shifting downward due to a gap between the fan system fastener 440 and the fan system housing connector aperture 430. In certain embodiments, by maintaining the distance between the fan system housing connector 420 and a lower housing component (such as a GPU component array housing), this approach ensures that interference due to insufficient distance caused by accumulated tolerances is avoided. In certain embodiments, the GPU component array housing includes a GPU heat sink. In certain embodiments, GPU heat sink extends across some or all of a top portion of the GPU component array housing.

In certain embodiments, the fan system connector fastener mechanism 432 physically attaches the fan system housing connector to a fan system housing 440. In certain embodiments, the fan system housing 440 includes a base component 450, a top wall component 452. component, or a combination thereof. In certain embodiments, the base component 450 includes a bottom portion 454, a first side portion 456, a second side portion 458, or a combination thereof. In certain embodiments, a rear edge of the first side portion 456 extends beyond a rear edge of the bottom portion 454. In certain embodiments, a rear edge of the second side portion 458 extends beyond a rear edge of the bottom portion 454. In certain embodiments, a rear edge of the top wall component 452 extends horizontally beyond a rear edge of the bottom portion 454. In certain embodiments, a rear edge of the top wall component 452 extends horizontally beyond a rear edge of the first side portion 456. In certain embodiments, a rear edge of the top wall component 452 extends horizontally beyond a rear edge of the second side portion 458. In certain embodiments, a portion the top wall component 452 extends over a portion of a component array. In certain embodiments, the rear edge of the top wall component 452 extends across a portion of top of a component array. In certain embodiments, the component array includes a GPU component array which includes a GPU component array housing. In certain embodiments, the rear edge of the top wall component 452 extends over a portion of the GPU component array housing. In certain embodiments, the GPU component array housing includes a GPU heat sink. In certain embodiments, the GPU heat sink extends across some or all of a top portion of the GPU component array housing. In certain embodiments, the rear edge of the top wall component 452 extends over some or all of the GPU heat sink.

In certain embodiments, the top wall component 452 defines a first connector recess 460, a second connector recess 462, or a combination thereof. In certain embodiments, the first connector recess 460, the second connector recess 462, or a combination thereof, are positioned along a rear edge of the top wall component 452. In certain embodiments, a first fan system housing connector 420 is mounted within the first connector recess. In certain embodiments, a second fan system housing connector 420 is mounted within the second connector recess 462.

In certain embodiments, the top wall component 452 includes a first connector first fastener receptacle 470, a first connector second fastener receptacle 472, or a combination thereof. In certain embodiments, the first connector first fastener receptacle 470 and the first connector second fastener receptacle 472 are positioned on opposing edges of the first connector recess 460. In certain embodiments, the first connector first fastener receptacle 470 and the first connector second fastener receptacle 472 are configured to receive respective fan system connector fastener mechanisms 432. In certain embodiments, the top wall component 452 includes a second connector first fastener receptacle 474, a second connector second fastener receptacle 476, or a combination thereof. In certain embodiments, the second connector first fastener receptacle 474 and the second connector second fastener receptacle 476 are positioned on opposing edges of the second connector recess 462. In certain embodiments, the second connector first fastener receptacle 474 and the second connector second fastener receptacle 476 are configured to receive respective fan system connector fastener mechanisms 432.

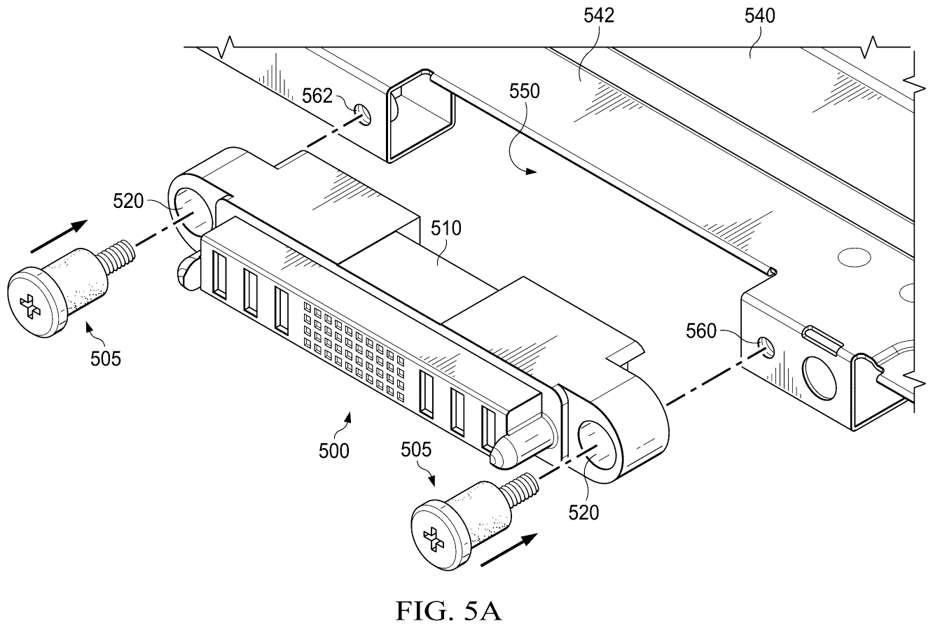

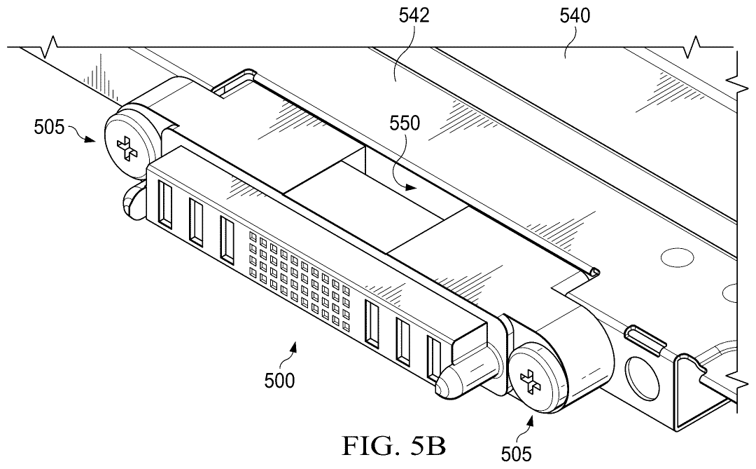

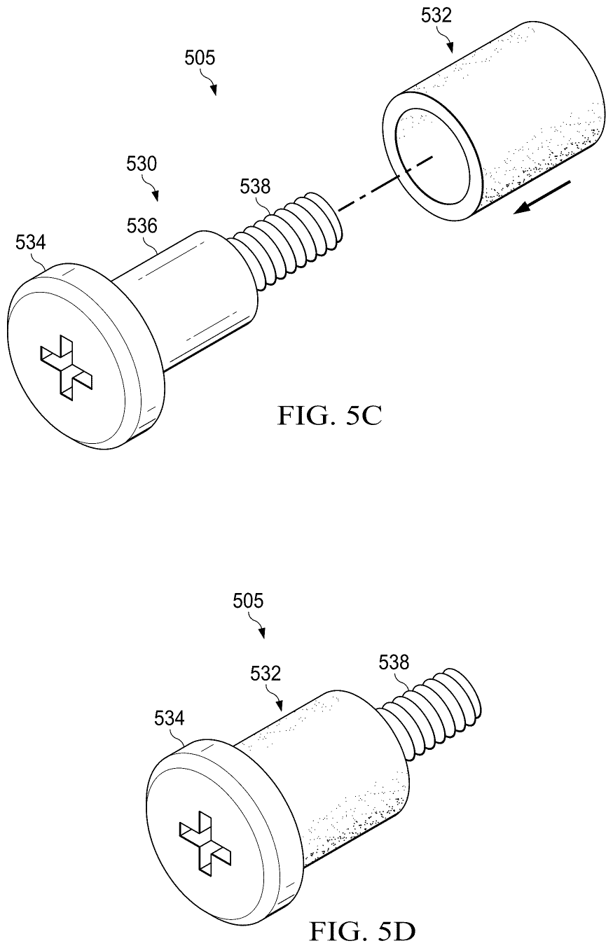

FIGS. 5A, 5B, 5C and 5D, generally referred to as FIG. 5, show views of a fan system connector system 500. More specifically, FIG. 5A shows an exploded perspective view of a fan system connector system 500. FIG. 5B shows a perspective view of a fan system connector system 500. FIG. 5C shows an exploded perspective view of a fan system connector fastener mechanism 505. FIG. 5D shows a perspective view of a fan system connector fastener mechanism 505. In certain embodiments, fan system connector system 500 corresponds to the fan system connector system of fan system 150.

In certain embodiments, the fan system connector system 500 includes a fan system housing connector 510. In certain embodiments, the fan system housing connector 510 is configured as a female type connector. In certain embodiments, the fan system housing connector 510 is configured to interconnect with a fan system cable connector. In certain embodiments, the fan system cable connector is configured as a male type connector.

In certain embodiments, the fan system housing connector 510 includes a fan system housing connector aperture 520, a fan system connector fastener mechanism 505, or a combination thereof. In certain embodiments, the fan system connector fastener mechanism 505 is configured to fit within the fan system housing connector aperture 520.

In certain embodiments, the fan system connector fastener mechanism 505 includes a fan system fastener 530 and a fan system connector positioning component 532. In certain embodiments, the fan system positioning component 532 is configured as a right circular, open cylinder. In certain embodiments, the cylindrical fan system positioning component 532 fits around the fan system fastener 530. In certain embodiments, the fan system fastener 530 includes a fastener head 534, a fastener cylindrical portion 536 and a fastener threaded portion 538. In certain embodiments, the cylindrical fan system positioning component 532 fits around the fastener cylindrical portion 536. In certain embodiments, the fan system positioning component 532 is configured with an elastomeric material. In certain embodiments, the elastomeric material is rubber.

In certain embodiments, the fan system positioning component 532 is sized to fill the gap between the fan system fastener 530 and the fan system housing connector aperture 520. In certain embodiments, so positioning the fan system positioning component 532 ensures that the centers of the fan system fastener 530 and the fan system housing connector aperture 520 align, thereby preventing the fan system connector 510 from shifting downward due to a gap between the fan system fastener 530 and the fan system housing connector aperture 520. In certain embodiments, by maintaining the distance between the fan system housing connector 510 and a lower housing component (such as a GPU component array), this approach ensures that interference due to insufficient distance caused by accumulated tolerances is avoided.

In certain embodiments, the fan system connector fastener mechanism 505 physically attaches the fan system housing connector to a fan system housing 540. In certain embodiments, the fan system housing 540 includes a top wall component 542. In certain embodiments, the top wall component 542 defines a connector recess 550. In certain embodiments, the connector recess 550 is positioned along a rear edge of the top wall component 542. In certain embodiments, the system housing connector 510 is mounted within the connector recess 550.

In certain embodiments, the top wall component 542 includes a connector first fastener receptacle 560, a connector second fastener receptacle 562, or a combination thereof. In certain embodiments, the connector first fastener receptacle 560 and the connector second fastener receptacle 562 are positioned on opposing edges of the connector recess 550. In certain embodiments, the connector first fastener receptacle 560 and the connector second fastener receptacle 562 are configured to receive respective fan system connector fastener mechanisms 505.

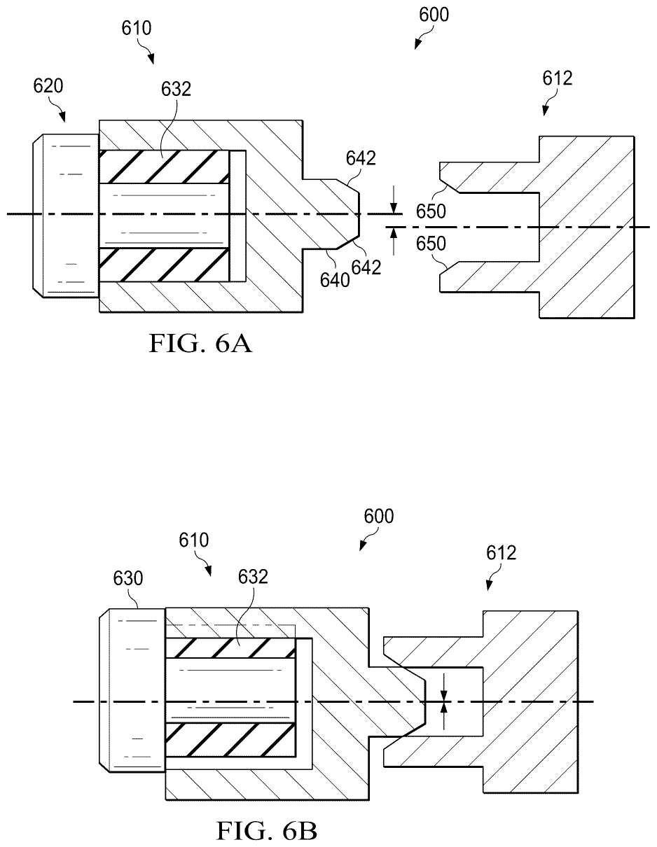

FIGS. 6A and 6B, generally referred to as FIG. 6, show views of a fan system connector system 600. More specifically, FIG. 6A shows a cross-sectional view of a fan system connector system 600 in a first position (e.g., an uninserted position). FIG. 6B shows a cross-sectional view of a fan system connector system 600 in a second position (e.g., a partially inserted position). In certain embodiments, the fan system connector system 600 corresponds to the fan system connector system of fan system 150.

In certain embodiments, the fan system connector system 500 includes a connector portion 610, a receptacle portion 612, or a combination thereof. In certain embodiments, the receptable portion 612 is included within a fan system housing of a fan system such as fan system 150. In certain embodiments, the connector portion 610 includes a fan system housing connector aperture 620, a fan system connector fastener mechanism 602 or a combination thereof. In certain embodiments, the fan system connector fastener mechanism 622 is configured to fit within the fan system housing connector aperture 620.

In certain embodiments, the fan system connector fastener mechanism 622 includes a fan system fastener 630 and a fan system connector positioning component 632. In certain embodiments, the fan system positioning component 632 is configured as a cylinder. In certain embodiments, the cylindrical fan system positioning component 632 fits around the fan system fastener 630. In certain embodiments, the fan system positioning component 632 is configured with an elastomeric material. In certain embodiments, the elastomeric material is rubber. In certain embodiments, if the connector portion 610 is misaligned as it is inserted into the receptacle portion 612, a portion of the fan system positioning component 632 may compress to facilitate insertion of the connector portion 610 into the receptacle portion 612.

In certain embodiments, the fan system connector mechanism includes a connector projection 640. In certain embodiments the fan system connector projection 640 includes a portion of a fan system fastener. In certain embodiments the fan system connector projection 640 includes a threaded portion of a fan system fastener. In certain embodiments, the connector projection 640 includes an angled insertion portion 640. In certain embodiments, the angled insertion portion 642 is positioned along an edge of the connector projection 640. In certain embodiments, the angled insertion portion 642 has a first diameter at the edge of the connector projection and a second diameter internal to the edge of the connector. In certain embodiments, the first diameter is less than the second diameter.

In certain embodiments, the receptacle portion 612 includes an angled receptor portion 650. In certain embodiments, the angled receptor portion 650 is positioned along an edge of a recess of the receptacle portion 650. In certain embodiments, the angled receptor portion 650 has a first diameter at the edge of the recess of the receptacle portion 650 and a second diameter internal to the edge of the recess of the receptacle portion 650. In certain embodiments, the first diameter is less than the second diameter. In certain embodiments, the angled insertion portion 642 and the angled receptor portion 650 interact to simultaneously position and align the connector portion 610 as the connector portion 610 is inserted into the receptacle portion 612.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A fan system connector system for use with an information handling system, comprising:
a fan system housing connector, the fan system housing connector defining a fan system housing connector aperture; and,
a fan system housing connector fastener mechanism, the fan system housing connector fastener mechanism comprising a fan system housing fastener and a fan system housing fastener positioning component, the fan system housing connector fastener mechanism being configured to attach the fan system housing connector to a fan system housing, the fan system housing connector fastener mechanism being configured to fit within the fan system housing connector aperture.

2. The fan system connector system of claim 1, wherein:
the fan system housing fastener positioning component is configured with an elastomeric material.

3. The fan system connector system of claim 1, wherein:
the fan system housing fastener positioning component is configured as a right circular, open cylinder.

4. The fan system connector system of claim 3, wherein:
the fan system housing fastener includes a fastener head, a fastener cylindrical portion and a fastener threaded portion; and,
the fan system housing fastener positioning component fits around the fastener cylindrical portion.

5. The fan system connector system of claim 1, wherein:
the fan system housing includes a top wall component; and,
the fan system housing connector is attached to the top wall component.

6. The fan system connector system of claim 5, wherein:
a portion of the top wall component extends over a portion of a component array.

7. A fan system for use with an information handling system comprising:
a fan system housing; and,
a fan system connector system, the fan system connector system comprising:
a fan system housing connector, the fan system housing connector defining a fan system housing connector aperture; and,
a fan system housing connector fastener mechanism, the fan system housing connector fastener mechanism comprising a fan system housing fastener and a fan system housing fastener positioning component, the fan system housing connector fastener mechanism being configured to attach the fan system housing connector to the fan system housing, the fan system housing connector fastener mechanism being configured to fit within the fan system housing connector aperture.

8. The bottom system of claim 7, wherein:
the fan system housing fastener positioning component is configured with an elastomeric material.

9. The bottom system of claim 7, wherein:
the fan system housing fastener positioning component is configured as a right circular, open cylinder.

10. The bottom system of claim 9, wherein:
the fan system housing fastener includes a fastener head, a fastener cylindrical portion and a fastener threaded portion; and,
the fan system housing fastener positioning component fits around the fastener cylindrical portion.

11. The bottom system of claim 7, wherein:
the fan system housing includes a top wall component; and,
the fan system housing connector is attached to the top wall component.

12. The bottom system of claim 11, wherein:
a portion of the top wall component extends over a portion of a component array.

13. A system comprising:
a chassis;
a component array; and,
a fan system, the fan system comprising
a fan system housing; and,
a fan system connector system, the fan system connector system comprising:
a fan system housing connector, the fan system housing connector defining a fan system housing connector aperture; and,
a fan system housing connector fastener mechanism, the fan system housing connector fastener mechanism comprising a fan system housing fastener and a fan system housing fastener positioning component, the fan system housing connector fastener mechanism being configured to attach the fan system housing connector to the fan system housing, the fan system housing connector fastener mechanism being configured to fit within the fan system housing connector aperture.

14. The system of claim 13, wherein:
the fan system housing fastener positioning component is configured with an elastomeric material.

15. The system of claim 13, wherein:
the fan system housing fastener positioning component is configured as a right circular, open cylinder.

16. The system of claim 15, wherein:
the fan system housing fastener includes a fastener head, a fastener cylindrical portion and a fastener threaded portion; and,
the fan system housing fastener positioning component fits around the fastener cylindrical portion.

17. The system of claim 13, wherein:
the fan system housing includes a top wall component; and,
the fan system housing connector is attached to the top wall component.

18. The system of claim 17, wherein:
a portion of the top wall component extends over a portion of a component array.
